(19) United States
(12) Patent Application Publication
(10) Pub. No.: US 2011/0130007 A1
(43) Pub. Date: Jun. 2, 2011

(54) IN-SITU CLEAN TO REDUCE METAL RESIDUES AFTER ETCHING TITANIUM NITRIDE

(75) Inventors: CHI-HONG CHING, Santa Clara, CA (US); CHANG-LIN HSIEH, San Jose, CA (US); JIE ZHOU, Sunnyvale, CA (US)

(73) Assignee: APPLIED MATERIALS, INC., Santa Clara, CA (US)

(21) Appl. No.: 12/884,609

(22) Filed: Sep. 17, 2010

Related U.S. Application Data
(60) Provisional application No. 61/254,818, filed on Oct. 26, 2009.

(51) Int. Cl. H01L 21/467

(52) U.S. Cl. 438/710; 257/E21.486

(57) ABSTRACT

Methods of processing substrates having titanium nitride layers are provided. In some embodiments, a method for processing a substrate having a dielectric layer to be etched, a titanium nitride layer above the dielectric layer, and a patterned photoresist layer above the titanium nitride layer, includes etching a pattern into the titanium nitride layer by exposing the titanium nitride layer to a first plasma comprising a chlorine containing gas to form a hard mask; removing titanium nitride etch residues disposed on one or more surfaces of the process chamber and/or substrate by forming a second plasma in the process chamber from a reactive gas comprising at least one of carbon monoxide or carbon dioxide; and etching the dielectric layer through the hard mask with a third plasma comprising a fluorocarbon gas.

### CROSS-REFERENCE TO RELATED APPLICATIONS

This application claims benefit of U.S. provisional patent application Ser. No. 61/254,818, filed Oct. 26, 2009, which is herein incorporated by reference

### FIELD

Embodiments of the present invention generally relate to semiconductor processing and, more particularly, to methods of processing substrates having titanium nitride (TiN) hard masks.

### BACKGROUND

Integrated circuits have evolved into complex devices that can include millions of components (e.g., transistors, capacitors and resistors) on a single chip. The evolution of chip designs continually requires faster circuitry and greater circuit density. The demands for greater circuit density necessitate a reduction in the dimensions of the integrated circuit components.

The overall size of the integrated circuit components are limited by the smallest geometrical feature that can be etched into the substrate, the critical dimension (CD). One technique for etching dielectric layers on substrates to facilitate greater control of the critical dimension utilizes a titanium nitride hard mask. Titanium nitride is used as a hard mask material because it provides high selectivity between the hard mask and the dielectric layer, thereby facilitating control of the critical dimension while also protecting the underlying dielectric layer, reducing the risk of damage to the dielectric layer and preserving k-value integrity.

However, conventional processing using such titanium nitride hard masks requires separate task-specific etching chambers to perform multi-step processing. For example, a metal etching chamber is used for hard mask patterning and a dielectric etching chamber is for underlying dielectric layers etching. Since residual hard mask material (e.g., titanium nitride) typically remains on the surfaces of the etching chamber and the substrate itself, subsequent etching processes performed in the same process chamber often result in contamination of the substrate and/or reduction in uniformity of the subsequent etching processes. Accordingly, the substrate is typically removed from the etching chamber, cleaned, and placed into a second etching chamber for additional processing (e.g., etching underlying layers through the hard mask). However, the process of removing the substrate for cleaning between etching processes and placing the substrate in a second process chamber reduces efficiency and productivity.

Therefore, the inventors have provided an improved method of processing substrates using titanium nitride hard masks.

### SUMMARY

Methods of processing substrates having titanium nitride layers are provided herein. In some embodiments, a method for processing a substrate having a dielectric layer to be etched, a titanium nitride (TiN) layer disposed above the dielectric layer, and a patterned photoresist layer disposed above the titanium nitride layer may include etching a pattern into the titanium nitride layer by exposing the titanium nitride layer to a first plasma comprising a chlorine containing gas to form a hard mask; removing titanium nitride etch residues disposed on one or more surfaces of the process chamber and/or the substrate by forming a second plasma in the process chamber from a reactive gas comprising at least one of carbon monoxide (CO) or carbon dioxide (CO₂); and etching the dielectric layer through the hard mask with a third plasma comprising a fluorocarbon gas.

In some embodiments, the inventive methods disclosed herein may be implemented in a computer readable medium, having instructions stored thereon which, when executed by a controller, causes a process chamber having a substrate disposed therein to be etched by the inventive methods described herein.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only exemplary embodiments of this invention and are therefore not to be considered limiting of its scope, for the invention may admit to other equally effective embodiments.

FIG. 1 depicts a method for the processing of a semiconductor substrate in accordance with some embodiments of the present invention.

FIGS. 2A-2D are illustrative cross-sectional views of a substrate during different stages of the processing sequence in accordance with some embodiments of the present invention.

FIG. 3 depicts an apparatus suitable for processing semiconductor substrates in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention generally relate to methods for processing substrates having titanium nitride layers. In some embodiments, the inventive methods remove by-products resultant from etching titanium nitride layers, such as a titanium nitride hard mask. The inventive methods may advantageously increase productivity and efficiency of processing semiconductor substrates by removing titanium nitride etching residues in-situ, thereby eliminating the need for a multi-chamber etching processes when etching other layers, such as dielectric layers, after etching the titanium nitride layer.

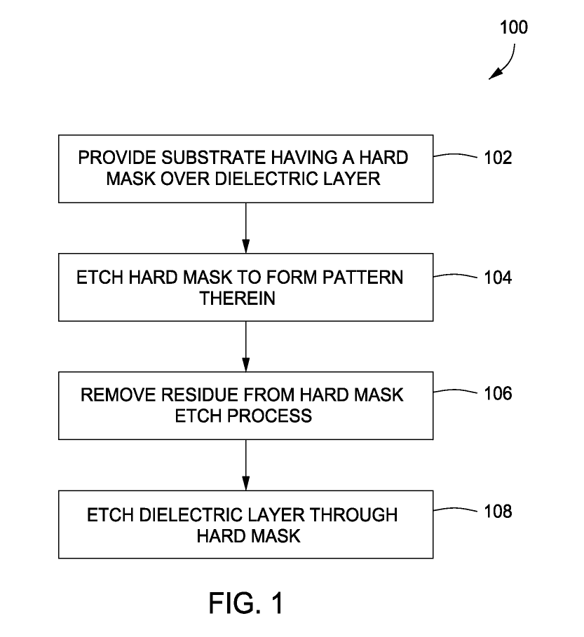

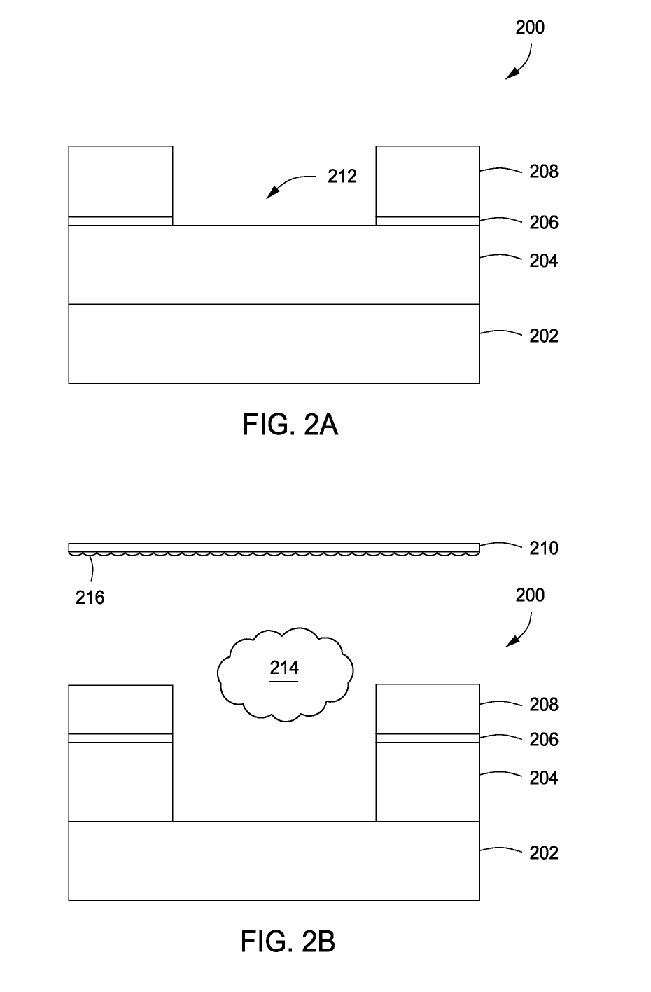

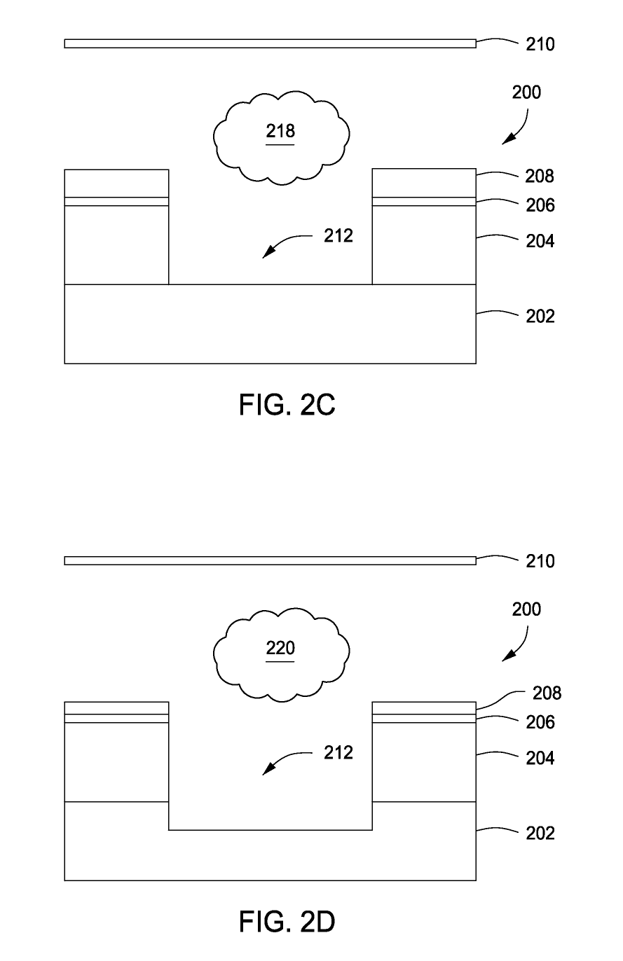

FIG. 1 depicts a method for the processing of a semiconductor substrate in accordance with some embodiments of the present invention. FIGS. 2A-2D are illustrative cross-sectional views of a substrate during different stages of the process sequence in accordance with some embodiments of the present invention. To best understand the invention, the reader should refer simultaneously to FIG. 1 and FIGS. 2A-2D.

The method 100 begins at 102, where a substrate 200, having a titanium nitride hard mask 204 disposed over a dielectric layer 202, is provided (as depicted in FIG. 2A). The substrate 200 may be any suitable substrate, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a light emitting diode (LED) substrate, a solar cell array, solar panel, or the like. In some embodiments, the substrate 200 may be a semiconductor wafer (e.g., a 200 mm, 300 mm, or the like silicon wafer).

The substrate 200 includes a dielectric layer 202 to be etched, a titanium nitride layer 204 disposed above the dielectric layer 202, and a photoresist layer 208 disposed above the titanium nitride layer 204. In some embodiments, an anti-reflective layer 206 may be disposed between the titanium nitride layer 204 and the photoresist layer 208. The substrate 200 may also include different and/or additional material layers. In addition, features, such as trenches, vias, or the like, may be formed in one or more layers of the substrate 200.

In some embodiments, the dielectric layer 202 may comprise silicon oxide (SiO₂), silicon nitride (SiN), a low-k material, or the like. The low-k material may be a carbon-doped dielectric material, such as carbon-doped silicon oxide (SiOC), organic polymers (such as polyimide, parylene), organic doped silicon glass (OSG), fluorine doped silicon glass (FSG), and the like. As used herein, low-k materials are materials having a dielectric constant less than that of undoped silicon oxide, which is about 3.9.

The titanium nitride layer 204 may be formed over the dielectric layer 202 in any suitable manner, such as by chemical vapor deposition (CVD), physical vapor deposition (PVD), or the like. In some embodiments, the titanium nitride layer 204 may be formed into a hard mask and utilized to facilitate etching a pattern or feature 212 into the dielectric layer 202. For example, the photoresist layer 208 may be deposited and patterned over the titanium nitride layer 204 to define a pattern or feature 212 that expose portions of the underlying titanium nitride layer 204 that are to be removed to form the hard mask.

The photoresist layer 208 may comprise any suitable photoresist, such as a positive or negative photoresist that may be formed and patterned in any suitable manner as known in the art. In some embodiments, the anti-reflective layer 206 may be provided to facilitate improved control over the patterning of the photoresist layer 208. The anti-reflective layer 206 may comprise any suitable anti-reflective materials, such as organic materials (such as polyamides and polysulfones, or inorganic materials such as silicon nitride (SiN), silicon oxynitride (SiON), silicon carbide (SiC), and the like). The anti-reflective layer 206 may be formed in any suitable manner as known in the art. When present, the anti-reflective layer 206 may be etched through the photoresist layer 208 as part of the photoresist patterning process, while etching the titanium nitride layer 204, or during a separate process.

Next, at 104, the titanium nitride layer 204 may then be etched to transfer the pattern or feature 212 of the photoresist layer 208 to the titanium nitride layer 204, thereby defining a titanium nitride hard mask 222 having the pattern or feature 212 defined therein (as shown in FIG. 2B). For example, in some embodiments, the pattern or feature 212 may be etched into the titanium nitride layer 204 by exposing the titanium nitride layer 204 to a first plasma 214 formed from a chlorine (Cl₂) containing gas. The chlorine containing gas is introduced into the process chamber via a gas source coupled to a gas inlet of the process chamber, such as an internal showerhead 210. In some embodiments, the chlorine containing gas is provided to the process chamber at a flow rate of between about 25 to about 150 sccm. Inert gases, such as argon, may be used to dilute the flow of the chlorine-containing gas. The argon to chlorine-containing gas flow rate ratio may be about 2:1 and higher.

In some embodiments, about 100 to about 500 W of source power may be provided to ignite the chlorine containing gas and form the first plasma 214. In some embodiments, a bias power may be applied to the substrate 200 to facilitate directing ions from the plasma towards the substrate. In some embodiments, the bias power may be about 100 to about 400 W. A process chamber pressure of between about 20 mTorr to about 400 mTorr may be maintained while igniting the process gas to promote plasma ignition and stability. The substrate 200 may be maintained at a temperature of between about 25 to about 50 degrees Celsius while etching the titanium nitride layer 204.

As a result of the etching process, residual hard mask material (titanium nitride etch residues 216) may be left on the substrate 200 and on components of the process chamber, such as chamber walls, showerheads, or the like (residue illustratively depicted on showerhead 210 in FIG. 2B). Accordingly, next, at 106, the titanium nitride etch residues 216 are removed from the substrate 200 surfaces and the showerhead 210 (as shown in FIG. 2C). In some embodiments, the titanium nitride etch residues 216 may be removed by exposing the substrate 200 and the showerhead 210 to a second plasma 218 formed from a process gas including a reactive gas comprising at least one of carbon monoxide (CO) or carbon dioxide (CO₂). The inventors have discovered that too much oxygen during the residue removal step undesirably reacts with the titanium nitride hard mask 222. For example, oxygen molecules tend to interact with titanium molecules to form titanium compounds and become residues. Accordingly, in some embodiments, the process gas for forming the second plasma excludes diatomic oxygen (O₂). In some embodiments, the process gas may further comprise an inert gas, such as helium (He), neon (Ne), argon (Ar), or the like.

The process gas may be provided to the process chamber via a gas source coupled to the process chamber (such as the showerhead 210) at a total flow rate of between about 100 to about 600 sccm. In embodiments where just the reactive gas or gases are provided, such gases may be provided at the flow rates disclosed above. In embodiments where the reactive gases are provided with one or more inert gases, a flow rate ratio of reactive gases to inert gases may be between about 2:1 to about 5:1.

In some embodiments, up to about to 100 W of RF power may be provided to facilitate igniting the process gas, forming the second plasma 218. In addition, or alternatively, up to about 500 W of bias RF power may be provided during ignition of the process gas and/or the removal of the titanium nitride etch residues 216 from the substrate 200 and process chamber surfaces. A process chamber pressure of between about 20 mTorr to about 400 mTorr may be maintained while igniting the process gas to promote plasma ignition and stability. The substrate 200 may be maintained at a temperature of between about 25 to about 50 degrees Celsius during the titanium nitride etch residue removal.

Next, at 108, the pattern or feature 212 is etched into the dielectric layer 202 through the hard mask 204, as depicted in FIG. 2D. In some embodiments, the pattern or feature 212 may be etched into the dielectric layer 202 by exposing the substrate 200 to a third plasma 220 formed from a process gas comprising a fluorocarbon gas. In some embodiments, the process gas may further comprise oxygen (O₂) and/or an inert gas, such as helium (He), neon (Ne), argon (Ar), or the like. In some embodiments, the process gas is provided to the process chamber via a gas source coupled to the process chamber at a total flow rate of between about 200 to about 800 sccm, or about 800 sccm. In embodiments where oxygen is provided, the flow rate ratio of the fluorocarbon gas to oxygen may be between about 1:1 to about 2:1. In embodiments where an inert gas is provided, the flow rate ratio of the fluorocarbon gas to the inert gas may be between about 1:1 to about 1:15.

Upon completion of etching the pattern or feature into the dielectric layer 202, the method 100 generally ends. The substrate 200 may then continue being processed as desired. For example, the photoresist layer 108 and, optionally, the anti-reflective coating layer 106 may be removed. In some embodiments, the titanium nitride hard mask layer may be removed, although in some embodiments, the titanium nitride hard mask layer may remain on the substrate. Generally, the substrate 200 may continue being processed as desired to complete the devices and/or structures being fabricated on the substrate.

Although only a single feature 212 is depicted in FIGS. 2A-D, the inventive methods are suitable for use in connection with forming single or dual damascene structures, contacts, vias, trenches, or any other feature or pattern where a titanium nitride layer is used as a hard mask to etch an underlying dielectric layer. In addition, the inventive titanium nitride etch and residue removal techniques are further applicable to other applications where titanium nitride layers are etched, such as for example, barrier layers, etch stop layers, or the like.

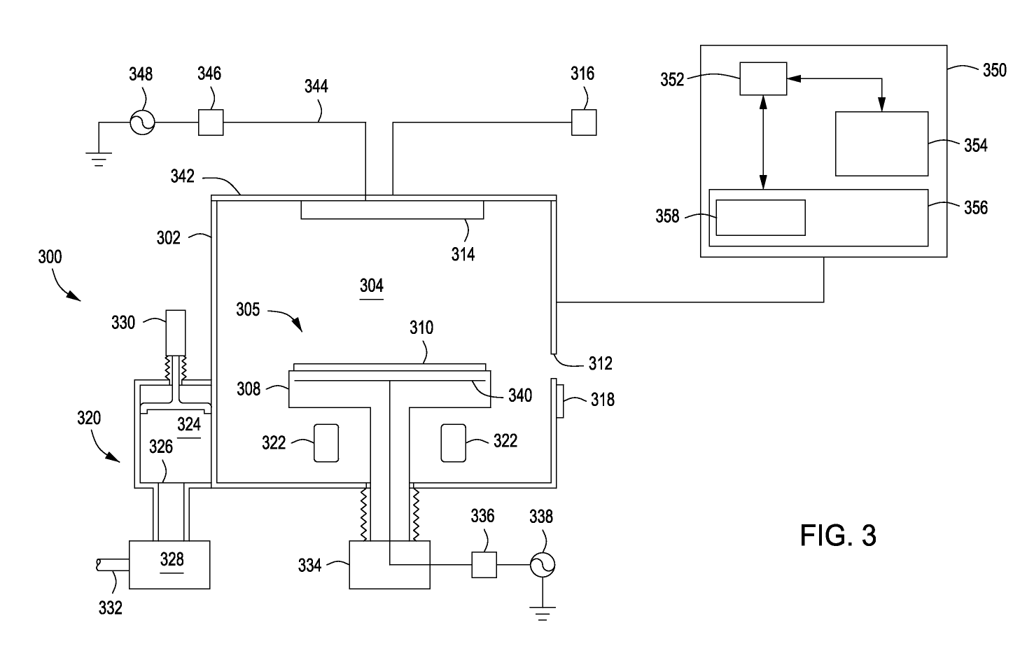

FIG. 3 depicts an apparatus 300 suitable for processing a substrate in accordance with some embodiments of the present invention. The apparatus 300 may comprise a controller 350 and a process chamber 302 having an exhaust system 320 for removing excess process gases, processing by-products, or the like, from the interior of the process chamber 305. Exemplary process chambers may include the DPS®, ENABLER®, ADVANTEDGE™, or other process chambers, available from Applied Materials, Inc. of Santa Clara, Calif. Other suitable process chambers may similarly be used.

The process chamber 302 has an inner volume 305 that may include a processing volume 304. The processing volume 304 may be defined, for example, between a substrate support pedestal 308 disposed within the process chamber 302 for supporting a substrate 310 thereupon during processing and one or more gas inlets, such as a showerhead 314 and/or nozzles provided at desired locations. In some embodiments, the substrate support pedestal 308 may include a mechanism that retains or supports the substrate 310 on the surface of the substrate support pedestal 308, such as an electrostatic chuck, a vacuum chuck, a substrate retaining clamp, or the like (not shown). In some embodiments, the substrate support pedestal 308 may include mechanisms for controlling the substrate temperature (such as heating and/or cooling devices, not shown) and/or for controlling the species flux and/or ion energy proximate the substrate surface.

For example, in some embodiments, the substrate support pedestal 308 may include an RF bias electrode 340. The RF bias electrode 340 may be coupled to one or more bias power sources (one bias power source 338 shown) through one or more respective matching networks (matching network 336 shown). The one or more bias power sources may be capable of producing up to 10,000 W at a frequency of about 2 MHz, or about 13.56 MHz, or about 60 Mhz. In some embodiments, two bias power sources may be provided for coupling RF power through respective matching networks to the RF bias electrode 340 at respective frequencies of about 2 MHz and about 13.56 MHz. In some embodiments, three bias power sources may be provided for coupling RF power through respective matching networks to the RF bias electrode 340 at respective frequencies of about 2 MHz, about 13.56 MHz, and about 60 Mhz. The at least one bias power source may provide either continuous or pulsed power. In some embodiments, the bias power source alternatively may be a DC or pulsed DC source.

The substrate 310 may enter the process chamber 302 via an opening 312 in a wall of the process chamber 302. The opening 312 may be selectively sealed via a slit valve 318, or other mechanism for selectively providing access to the interior of the chamber through the opening 312. The substrate support pedestal 308 may be coupled to a lift mechanism 334 that may control the position of the substrate support pedestal 308 between a lower position (as shown) suitable for transferring substrates into and out of the chamber via the opening 312 and a selectable upper position suitable for processing. The process position may be selected to maximize process uniformity for a particular process. When in at least one of the elevated processing positions, the substrate support pedestal 308 may be disposed above the opening 312 to provide a symmetrical processing region.

The one or more gas inlets (e.g., the showerhead 314) may be coupled to a gas supply 316 for providing one or more process gases into the processing volume 304 of the process chamber 302. Although a showerhead 314 is shown in FIG. 3, additional or alternative gas inlets may be provided such as nozzles or inlets disposed in the ceiling or on the sidewalls of the process chamber 302 or at other locations suitable for providing gases as desired to the process chamber 302, such as the base of the process chamber, the periphery of the substrate support pedestal, or the like.

In some embodiments, the apparatus 300 may utilize capacitively coupled RF power for plasma processing, although the apparatus may also or alternatively use inductive coupling of RF power for plasma processing. For example, the process chamber 302 may have a ceiling 342 made from dielectric materials and a showerhead 314 that is at least partially conductive to provide an RF electrode (or a separate RF electrode may be provided). The showerhead 314 (or other RF electrode) may be coupled to one or more RF power sources (one RF power source 348 shown) through one or more respective matching networks (matching network 346 shown). The one or more plasma sources may be capable of producing up to about 3,000 or about 5,000 W at a frequency of about 2 MHz and or about 13.56 MHz or high frequency, such as about 60 MHz or about 162 MHz. The exhaust system 320 generally includes a pumping plenum 324 and one or more conduits that couple the pumping plenum 324 to the inner volume 305 (and generally, the processing volume 304) of the process chamber 302.

A vacuum pump 328 may be coupled to the pumping plenum 324 via a pumping port 326 for pumping out the exhaust gases from the process chamber 302. The vacuum pump 328 may be fluidly coupled to an exhaust outlet 332 for routing the exhaust as required to appropriate exhaust handling equipment. A valve 330 (such as a gate valve, or the like) may be disposed in the pumping plenum 324 to facilitate control of the flow rate of the exhaust gases in combination with the operation of the vacuum pump 328. Although a z-motion gate valve is shown, any suitable, process compatible valve for controlling the flow of the exhaust may be utilized.

To facilitate control of the process chamber 302 as described above, the controller 350 may be one of any form of general-purpose computer processor that can be used in an industrial setting for controlling various chambers and sub-processors. The memory, or computer-readable medium, 356 of the CPU 352 may be one or more of readily available memory such as random access memory (RAM), read only memory (ROM), floppy disk, hard disk, or any other form of digital storage, local or remote. The support circuits 354 are coupled to the CPU 352 for supporting the processor in a conventional manner. These circuits include cache, power supplies, clock circuits, input/output circuitry and subsystems, and the like.

The inventive methods disclosed herein may generally be stored in the memory 356 as a software routine 358 that, when executed by the CPU 352, causes the process chamber 302 to perform processes of the present invention. The software routine 358 may also be stored and/or executed by a second CPU (not shown) that is remotely located from the hardware being controlled by the CPU 352. Some or all of the method of the present invention may also be performed in hardware. As such, the invention may be implemented in software and executed using a computer system, in hardware as, e.g., an application specific integrated circuit or other type of hardware implementation, or as a combination of software and hardware. The software routine 358 may be executed after the substrate 310 is positioned on the pedestal 308. The software routine 358, when executed by the CPU 352, transforms the general purpose computer into a specific purpose computer (controller) 350 that controls the chamber operation such that the methods disclosed herein are performed.

While the foregoing is directed to embodiments of the present invention, other and further embodiments of the invention may be devised without departing from the basic scope thereof.

1. A method for processing a substrate having a dielectric layer to be etched, a titanium nitride (TiN) layer disposed above the dielectric layer, and a patterned photoresist layer disposed above the titanium nitride layer, comprising:
etching a pattern into the titanium nitride layer by exposing the titanium nitride layer to a first plasma comprising a chlorine containing gas to form a hard mask;
removing titanium nitride etch residues disposed on one or more surfaces of the process chamber and/or the substrate by forming a second plasma in the process chamber from a reactive gas comprising at least one of carbon monoxide (CO) or carbon dioxide (CO₂); and
etching the dielectric layer through the hard mask with a third plasma comprising a fluorocarbon gas.

2. The method of claim 1, wherein the dielectric layer comprises at least one of silicon oxide (SiO₂), silicon nitride (SiN), or a low-k material.

3. The method of claim 1, wherein the substrate further comprises an anti-reflective layer disposed between the titanium nitride layer and the photoresist layer.

4. The method of claim 1, wherein the process is performed in a single process chamber.

5. The method of claim 1, wherein the chlorine containing gas is provided at a flow rate of between about 25 to about 150 sccm.

6. The method of claim 1, wherein at least one of forming the first plasma or forming the second plasma further comprises:
providing up to about 500 W of source RF power.

7. The method of claim 1, wherein forming the first plasma further comprises:
maintaining the process chamber at a pressure of between about 20 to about 400 mTorr.

8. The method of claim 1, wherein the process gas of the second plasma is provided at a flow rate of between about 100 to about 600 sccm.

9. The method of claim 1, wherein the second plasma further comprises an inert gas.

10. The method of claim 9, wherein a flow rate ratio of the reactive gas to the inert gas of the second plasma is between about 2:1 to about 5:1.

11. The method of claim 1, wherein forming the second plasma further comprises:
maintaining the process chamber at a pressure of between about 20 to about 400 mTorr.

12. The method of claim 1, wherein the flow rate of the fluorocarbon gas is between about 200 to about 800 sccm.

13. The method of claim 1, wherein the third plasma further comprises oxygen (O₂).

14. The method of claim 1, further comprising:
removing the photoresist layer with the second plasma while removing residues from the one or more surfaces of the process chamber.

15. A computer readable medium, having instructions stored thereon which, when executed by a controller, causes a process chamber having a substrate disposed therein to be etched by a method, wherein the substrate includes a dielectric layer to be etched, a titanium nitride layer disposed above the dielectric layer, and a patterned photoresist layer disposed above the hard mask, the method comprising:
etching a pattern into the titanium nitride layer by exposing the titanium nitride layer to a first plasma comprising a chlorine containing gas to form a hard mask;
removing titanium nitride etch residues disposed on one or more surfaces of the process chamber and/or the substrate by forming a second plasma in the process chamber from a reactive gas comprising at least one of carbon monoxide (CO) or carbon dioxide (CO₂); and
etching the dielectric layer through the hard mask with a third plasma comprising a fluorocarbon gas.

16. The computer readable medium of claim 15, wherein the process is performed in a single process chamber.

17. The computer readable medium of claim 16, wherein the chlorine containing gas is provided at a flow rate of between about 25 to about 150 sccm, wherein the process gas of the second plasma is provided at a flow rate of between about 100 to about 600 sccm, and wherein the flow rate of the fluorocarbon containing gas is between about 200 to about 800 sccm.

18. The computer readable medium of claim 15, wherein either or both of forming the first plasma or forming the second plasma further comprises:
providing up to about 500 W of source RF power; and
maintaining the process chamber at a pressure of between about 20 to about 400 mTorr.

19. The computer readable medium of claim 15, wherein the second plasma further comprises an inert gas, and wherein a flow rate ratio of the reactive gas to the inert gas of the second plasma is between about 2:1 to about 5:1.

20. The computer readable medium of claim 15, wherein the third plasma further comprises oxygen (O₂).
